(19) United States
(12) Patent Application Publication
(10) Pub. No.: US 2024/0419851 A1
(43) Pub. Date: Dec. 19, 2024

(54) COMPUTER-IMPLEMENTED METHOD FOR SIMULATING AN ACCIDENT OF A MOTOR VEHICLE USING AN ARTIFICIAL NEURAL NETWORK

(71) Applicant: Dr. Ing. h. c. F. Porsche AG, Stuttgart (DE)

(72) Inventors: Mohamed Karim Belaid, Passau (DE); Maximilian Rabus, Stuttgart (DE)

(21) Appl. No.: 18/650,711

(22) Filed: Apr. 30, 2024

(30) Foreign Application Priority Data
Jun. 15, 2023 (DE) 10 2023 115 585.7

(51) Int. Cl. G06F 30/15; G06F 30/27

(52) U.S. Cl. CPC G06F 30/15; G06F 30/27

(57) ABSTRACT

A computer-implemented method for simulating an accident of a motor vehicle using an artificial neural network (1). The method includes receiving input data (14) related to the accident; transforming the input data (14) into transformation data (12); and simulating the accident by means of the artificial neural network (1) using the transformation data (12).

### CROSS-REFERENCE TO RELATED APPLICATION

This application claims priority on German Patent Application No 10 2023 115585.7 filed Jun. 15, 2023, the entire disclosure of which is incorporated herein by reference.

### FIELD OF THE INVENTION

The invention relates to a computer-implemented method for simulating an accident of a motor vehicle using an artificial neural network.

### BACKGROUND OF THE INVENTION

DE 10 2020 115 192 A1 is earlier work by the assignee of the subject invention and discloses a method for simulating an accident of a motor vehicle using an artificial neural network. Input scalars associated with the accident are transformed into a transformed signal in a hidden layer of the network. During the transformation, a mathematical convolution of the input scalars is carried out. The accident is simulated using the transformed signal. The disclosure of DE 10 2020 115 192 A1 is incorporated herein by reference.

An object of this invention is to create an improved method for simulating an accident of a motor vehicle.

### SUMMARY OF THE INVENTION

According to one aspect of the invention, input data related to the accident are received. The input data can describe properties of the motor vehicle, properties of individuals in the motor vehicle and/or other data. The input data can, for example, describe positions, lengths, widths, and/or heights of components and/or body parts.

The input data are transformed into transformation data. This can be done in a hidden layer of the artificial neural network, for example. The accident is simulated by the artificial neural network using the transformation data.

The artificial neural network may have an encoder-decoder architecture, for instance. Convolutions in different dimensions, for example, can be used. For example, a one-dimensional convolution can be used for the encoder and a two-dimensional convolution for the decoder.

A computer-implemented method, as used herein, can mean that the method is carried out using a digital processing means and a digital data memory, for example. The digital data memory can store instructions that can be read and executed by the processing means. The instructions can be configured to cause the processing means to carry out a method according to an embodiment of the invention when the instructions are executed.

According to one embodiment, the input data can be configured as an input signal. The transformation data can include scalars. The scalars can be converted into a transformation signal prior to the simulation, and the simulation can be carried out using the transformation signal.

This embodiment is advantageous because the scalars transformed from the input signal make it possible to explain how the input signal is processed by the artificial neural network during the simulation. The scalars can be generated in a hidden layer of the neural network, for example, and can be analyzed by a data specialist to determine the influence of the input signal on the simulation. It is also possible to check whether a suitable part of the input signal is being used.

The scalars can include information about the input signal. The transformation signal can, for instance, include several values relating to the acceleration of a body part of a person in the motor vehicle during the simulated accident.

In some embodiments, the input data can be input scalars.

The transformation data can be configured as a single transformation scalar. The transformation scalar can include an indication of a severity of the accident, for example. For example, the transformation scalar can include an indication of a maximum acceleration of a body, a body part, a component of the motor vehicle, or the motor vehicle, for instance.

This embodiment is particularly advantageous because the single transformation scalar comprises less information than the input data, making it easier for a data specialist to assess whether the correct part of the input data is being used and how the simulation is being affected by the input data. This improves both the precision and the understanding of how the transformation scalar is affected by the input data.

In some embodiments, the transformation can be carried out using a transformer architecture or an attention mechanism. In the context of this description, a transformer architecture is understood to be an architecture comprising series-connected encoders and series-connected decoders. It is possible for the encoders and the decoders to have different dimensions. In this embodiment, it is in particular possible to omit convolutions. Practical tests have shown that this embodiment produces particularly realistic results.

In some embodiments, the input data can be configured as input scalars. The transformation data can be configured as a first embedded signal and a second embedded signal. The first embedded signal can include indications of positions and movements of a body or body parts of a person, for instance, and the second embedded signal can include indications of positions and movements of components of the motor vehicle or the motor vehicle. In the context of this description, an embedded signal is understood to be a signal that does not appear outside the artificial neural network. Practical tests have shown that this embodiment produces particularly realistic results, for example, from the first and second signals.

In one embodiment, the first embedded signal and/or the second embedded signal can both be multidimensional. The signals can respectively include several values in several dimensions, for example, in 32 or more dimensions.

According to some embodiments, the transformation data in the simulation may affect only a current or a future state of the simulation. This can be achieved via the structure of the artificial neural network. For example, the neurons of the artificial neural network can receive only information and/or data from the past or the present.

In some embodiments, the transformation data can be input into an input layer of the artificial neural network. This is particularly advantageous if the artificial neural network has an architecture as described in DE 10 2020 132 042 A1. Practical tests have shown that this embodiment produces particularly realistic results.

In one embodiment, the transformation data can be input into different hidden layers of the artificial neural network and/or used at different times during the execution of the simulation. For example, a first subset of the transformation data can be used in a first layer and/or at a first time during the execution of the simulation, while a second subset of the transformation data can be used in a second layer and/or at a second time during the execution of the simulation.

This, too, is particularly advantageous if the artificial neural network has an architecture as described in DE 10 2020 132 042 A1. This embodiment can likewise produce particularly realistic results.

The execution of the simulation generates information and/or data that can be used to improve the accident safety of a motor vehicle by modifying one or more components.

Further features and advantages of the invention will become apparent from the following description of examples with reference to the accompanying figures. The same reference signs are used for the same or similar features and for features having the same or similar functions.

### BRIEF DESCRIPTION OF THE DRAWINGS

FIG. 1 is a schematic illustration of an artificial neural network according to one embodiment of the invention;

FIG. 2 is a schematic illustration of an artificial neural network according to one embodiment of the invention

FIG. 3 a schematic illustration of an artificial neural network according to one embodiment of the invention.

### DETAILED DESCRIPTION

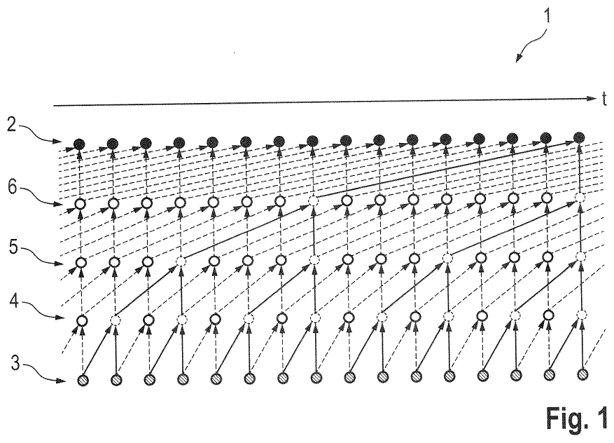

The artificial neural network 1 shown in FIG. 1 comprises an input layer 3, multiple hidden layers 4, 5, and 6, and an output layer 2. Each of the layers 2-6 comprises a plurality of artificial neurons shown as circles.

In FIG. 1, t represents the time elapsing during the execution of the simulation. Data are transmitted from the neurons in the direction from the input layer 3 via the hidden layers 4-6 to the output layer 2 exclusively to neurons of the respective next layer, which simulate the same point in time of the simulation or which simulate a later point in time of the simulation. This ensures that a later point in time of the simulation cannot affect an earlier point in time of the simulation.

For example, if data relating to a movement and/or a location of a motor vehicle or components of the motor vehicle are used as input data, and information about a movement and/or a location of a human body or human body parts are output in the output layer 2, later states of the components of the motor vehicle or the motor vehicle cannot affect earlier states of the body parts or the body. The simulation is thus carried out in a physically more realistic manner.

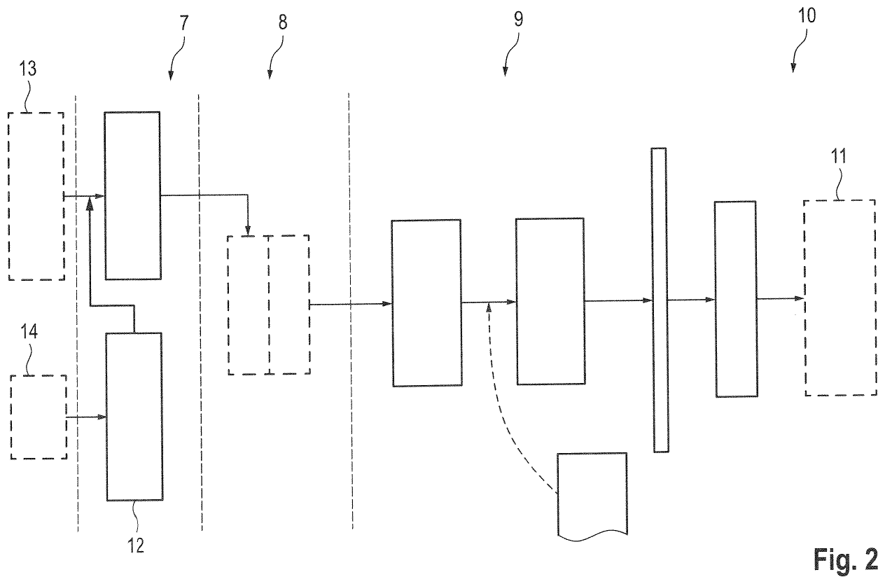

FIGS. 1 and 2 are block diagrams that illustrate hoe the artificial neral networks can be used to practice embodiments of the method described herein. It should be understood that the elements shown in the figures may be implemented in various forms of hardware, software or combinations thereof. Preferably, these elements are implemented in a combination of hardware and software on one or more appropriately programmed general-purpose devices, which may include a processor, memory and input/output interfaces. Elements that are shown as “coupled” can be connected directly or indirectly through one or more intermediate components. Such intermediate components may include both hardware and software-based components.

It will be appreciated by those skilled in the art that the block diagrams presented herein represent conceptual views embodying the principles of the disclosure. Similarly, it will be appreciated that these block diagrams or flow charts represent various processes that may be represented in computer readable media and so executed by a computer or processor, whether or not such computer or processor is explicitly shown.

The “computer” used to carry out the simulation of the invention may be understood to mean a machine or electronic circuitry or a high-performance computer, for example. In particular, a processor may be a master processor (central processing unit (CPU)), a microprocessor, or a microcontroller, for example an application-specific integrated circuit or a digital signal processor, optionally in combination with a memory unit for storing program instructions, etc. A processor may also be understood to mean a virtualized processor, a virtual machine, or a soft CPU. For example, it may also be a programmable processor equipped with configuration steps for carrying out the above-mentioned method according to the invention or configured with configuration steps in such a way that the programmable processor realizes the features according to the invention of the method, the component, the modules, or other aspects and/or partial aspects of the invention. In addition, highly parallel computing units and high-performance graphics modules may be provided.

The computer used to practice the method of this invention may include a “memory unit” or “memory module” such as a non-volatile memory in the form of a flash memory (Flash EEPROM) or a permanent memory, such as a hard drive. A “computer” also, for example, may be understood in connection with the invention to mean a processor and/or a memory unit for storing program instructions. For example, the processor is specifically configured to execute the program instructions in such a way that the processor executes functions to implement or realize the method according to the invention or a step of the method according to the invention.

The artificial neural network shown in FIG. 2 comprises an input layer 7, multiple hidden layers 8, 9, and 10, and an output layer 11. The artificial neural network can be structured as described in DE 10 2020 132 042 A1, for instance. Input data 14 are transformed into transformation data 12 in a dense layer. The transformation data 12 are input into the input layer 7 of the artificial neural network together with a one-dimensional vector 13. The one-dimensional vector 13 can relate to a location and/or a movement of a motor vehicle or parts of the motor vehicle, for example. The processing of the one-dimensional vector 13 and the transformation data 12 can be carried out as described in DE 10 2020 132 042 A1. A particularly realistic simulation is achieved by entering the transformation data 12 into the input layer 7.

The output data 11 output by the artificial neural network can, for instance, include an indication of a severity of the simulated accident. This can be a one-dimensional vector, for example. The severity of the accident can, for instance, be indicated by a severity of an injury to a body part. The output data also may be presented on a monitor so that a data expert can visualize the effect of the simulate accident on the vehicle and any passengers of the vehicle.

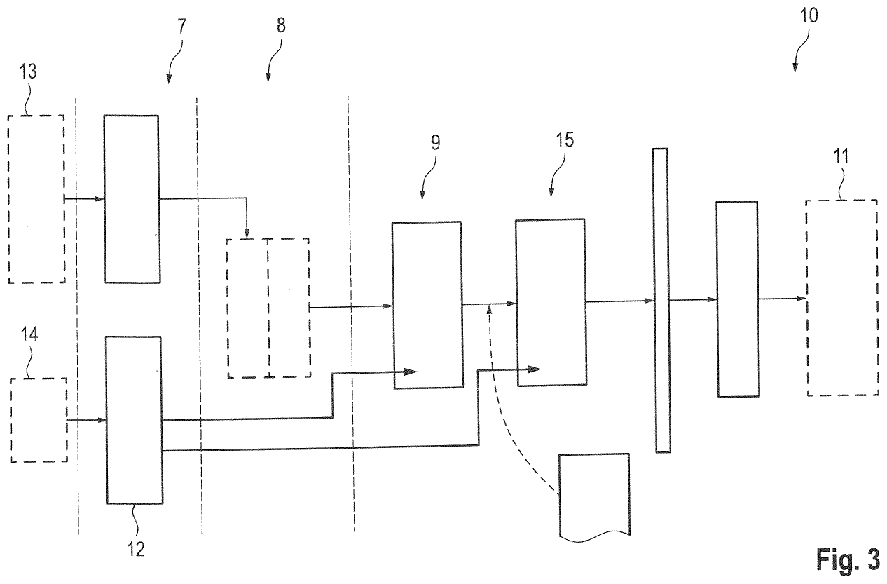

The artificial neural network shown in FIG. 3 is similar to the artificial neural network shown in FIG. 2. The transformation data 12 are not input into the input layer 7, however, but into different hidden layers 9 and 15. Under certain circumstances, depending on the type of accident being simulated, this can enable particularly realistic simulations, because the transformation data 12 can be input where they have a particularly high impact on the realism of the simulation. CLAIMS

1. A computer-implemented method for simulating an accident of a motor vehicle, the method comprising:
providing an artificial neural network (1) having an input layer (1), an output layer (2) and a plurality of hidden layers (3-6) between the input layer (1) and the output layer (2)
receiving input data (14) related to the accident;
transforming the input data (14) into transformation data (12) at the input layer (1);
simulating the accident by successively passing the transformation data (12) through the hidden layers (3-6) of the artificial neural network (1); and
outputting the effect of the simulated accident on the transformation data (12).

2. The method of claim 1, wherein the input data (14) are configured as an input signal, the transformation data (12) comprise scalars that are converted into a transformation signal prior to the simulation, and the simulation being carried out using the transformation signal.

3. The method of claim 1, wherein the input data (14) are configured as input scalars

4. The method of claim 1, wherein the transformation data (12) are configured as a single transformation scalar.

5. The method of claim 1, wherein the transformation is carried out using a transformer architecture or an attention mechanism.

6. The method of claim 1, wherein the input data (14) are configured as input scalars, and the transformation data (12) are configured as a first embedded signal and a second embedded signal.

7. The method of claim 1, wherein the first embedded signal and the second embedded signal are both multidimensional.

8. The method of claim 1, wherein, in the simulation, the transformation data (12) affect only a current or a future state of the simulation.

9. The method of claim 1, wherein the transformation data (12) are input into an input layer (3; 7) of the artificial neural network (1).

10. The method of claim 1, wherein the transformation data (12) are input into different layers (9; 15) of the artificial neural network (1) and/or used at different times during the execution of the simulation.
